(19) United States
(12) Patent Application Publication
(10) Pub. No.: US 2026/0145929 A1
(43) Pub. Date: May 28, 2026

(54) MEMS TRANSDUCER WITH MULTILAYER DEFLECTABLE MEMBRANE

(71) Applicant: Infineon Technologies AG, Neubiberg (DE)

(72) Inventors: Abhiraj Basavanna, München (DE); Alexander Frey, Lappersdorf (DE); Hans-Jörg Timme, Ottobrunn (DE); Marc Füldner, Neubiberg (DE)

(21) Appl. No.: 19/355,402

(22) Filed: Oct. 10, 2025

(30) Foreign Application Priority Data
Oct. 28, 2024 (DE) 102024131362.5

(51) Int. Cl. B81B 3/00

(52) U.S. Cl. CPC B81B 3/0072; B81B 2201/0235; B81B 2201/0257; B81B 2201/0285; B81B 2203/0127; B81B 2203/04

(57) ABSTRACT

A MEMS transducer includes a deflectable membrane where the deflectable membrane includes two first layers and a second layer arranged between the two first layers. The two first layers comprise low-stress silicon nitride, and the second layer comprises doped silicon.

This application claims priority to German Patent Application No. 102024131362.5, filed on Oct. 28, 2024, which application is hereby incorporated herein by reference in its entirety.

### TECHNICAL FIELD

Examples of the present disclosure relate to Micro-Electro-Mechanical-System (MEMS) transducers. In particular embodiments, examples of the present disclosure relate to MEMS transducers with a multilayer deflectable membrane.

### BACKGROUND

MEMS transducers, e.g., transducers which convert vibrations such as pressure waves or mechanical vibrations to an electrical signal, make use of a deflectable membrane. One aspect of the performance of such a deflectable membrane is its vibrational properties. In particular, a low damping over the frequency range of the application may be beneficial. However, achieving good vibrational properties is often diametral to the aim of a high robustness of the membrane. For example, MEMS transducers make use of fully clamped or free-floating membranes of high thickness to provide a sufficient robustness. Improving the trade-off between a good vibrational performance and a high robustness often comes with the drawback of either a high complexity in production or the introduction of special techniques which involve higher cost or time delay.

Accordingly, it would be desirable to provide a MEMS transducer providing an improved trade-off between a good vibrational performance, a high robustness, and a low complexity in production.

### SUMMARY

Examples of the present disclosure provide a MEMS transducer, comprising a deflectable membrane, the deflectable membrane comprising two first layers and a second layer arranged between the two first layers. The two first layers comprise low-stress silicon nitride, and the second layer comprises doped silicon.

### BRIEF DESCRIPTION OF THE DRAWINGS

Examples of the present disclosure are described in more detail below with respect to the figures, among which:

FIG. 1 illustrates a MEMS transducer, in particular, a membrane of a MEMS transducer, according to an example of the disclosure;

FIG. 2 illustrates a MEMS transducer, in particular, a membrane of a MEMS transducer, according to an example with corrugation;

FIG. 3 illustrates a capacitive MEMS transducer according to an example;

FIG. 4 illustrates a capacitive MEMS transducer with corrugated membrane and planar electrode according to an example;

FIG. 5 illustrates a capacitive MEMS transducer with corrugated membrane and planar electrode according to another example;

FIG. 6 illustrates a capacitive MEMS transducer with suspended mass according to an example;

FIG. 7 illustrates a capacitive MEMS transducer with planar electrode and suspended mass according to an example;

FIG. 8 illustrates a capacitive MEMS transducer with planar electrode and suspended mass according to another example;

FIG. 9 illustrates a conventional MEMS transducer.

### DETAILED DESCRIPTION OF ILLUSTRATIVE EMBODIMENTS

Examples of the present disclosure are now described in more detail with reference to the accompanying drawings, in which the same or similar elements or elements that have the same or similar functionality have the same reference signs assigned or are identified with the same name. In the following description, a plurality of details is set forth to provide a thorough explanation of examples of the disclosure. However, it will be apparent to one skilled in the art that other examples may be implemented without these specific details. In addition, features of the different examples described herein may be combined with each other, unless specifically noted otherwise.

Examples of the present disclosure relate to MEMS transducers. In particular, examples relate to MEMS transducers with a stacked low stress nitride membrane, e.g., with or without corrugation. Examples relate to MEMS sound transducers, e.g., microphones, e.g., single back plate (SBP) microphones. Further examples relate to vibration sensors, e.g., bone conduction microphones or voice pick-up units (VPU), e.g., acceleration sensors.

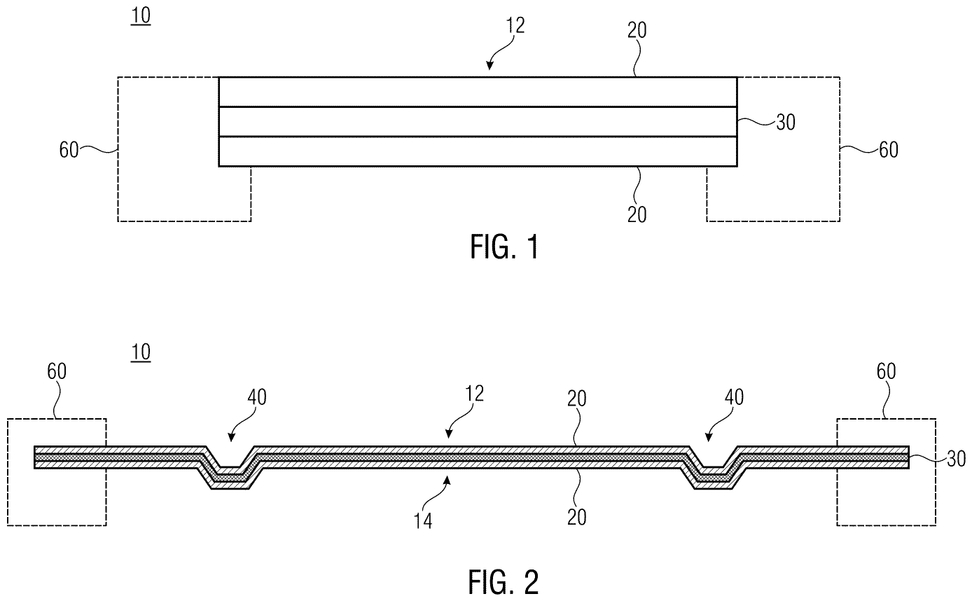

FIG. 1 illustrates a MEMS transducer 10 according to an example of the present disclosure. The MEMS transducer 10 comprises a deflectable membrane 12, which comprises two first layers 20 and a second layer 30. The second layer 30 is arranged between the two first layers 20. The two first layers 20 comprise low-stress silicon nitride. The second layer 30 comprises doped silicon, e.g., doped poly-silicon.

Examples of the disclosure may utilize the finding that a composite membrane structure comprising a layer comprising doped silicon between two layers comprising low-stress silicon nitride provides for a particularly low stress within the membrane, thereby resulting in a high robustness, and in particular, in an improved trade-off between robustness and vibrational or acoustic performance. In particular, examples may utilize the idea that the combination of silicon nitride, which provides a high robustness, with doped silicon facilitates the usage of silicon nitride, which might result in high stress when used alone.

Furthermore, examples of the disclosed structure is producible with a comparably low complexity and cost. In examples, the disclosed MEMS transducer may be produced using widely available methods. In other words, examples of the disclosure involve improving robustness without losing performance (substantial) by modifying the membrane stack to improve the areas of issues and thus opening up, e.g., for a design of a sound transducer, such as a microphone, which has very high mechanical compliance or acoustic performance along with high robustness.

For example, the doping of the silicon of the second layer 30 may contribute to a reduction of the stress in the membrane 12, or may allow for adjusting the stress of the second layer, and thus of the overall membrane 12. Adjustment of the stress may contribute to configuring the vibrational/acoustic properties of the membrane 12, e.g., according to a desired application of the MEMS transducer.

In examples, a concentration of a dopant of the doped silicon is in a range between 10¹⁹ cm⁻³ and 10²¹ cm⁻³.

For example, the deflectable membrane 12 may oscillate upon being excited by pressure oscillations such as sound waves or mechanical vibrations, e.g. caused by an acceleration of the MEMS transducer.

For example, the deflectable membrane 12 may be supported by a supporting structure 60, e.g., as shown for illustrative purpose in FIG. 1. For example, the supporting structure 60 may support or fix the deflectable membrane along a circumference of the deflectable membrane 12. The circumference may refer to a border of the deflectable membrane 12 extending in the plane, within which the layers of the membrane 12 extend.

For example, the deflectable membrane may be circular.

In examples the deflectable membrane 12 may have a radius is in a range between 200 μm to 750 μm or in a range of 250 μm to 500 μm.

In examples, the two first layers 20 consist of low-stress silicon nitride. Additionally or alternatively, the second layer 30 consists of doped silicon, e.g., doped poly-silicon.

In examples, the second layer 30 is arranged adjacent to each of the two first layers 20. In other words, in examples, the second layer 30 adjoins each of the two first layers 20.

In an example, the deflectable membrane 12 consists of the two first layers 20 and the second layer 30.

For example, low-stress silicon nitride may refer to silicon nitride having a stress below a predetermined value. For example, the stress in silicon nitride may be related to the ratio between silicon and nitrogen in the silicon nitride.

In examples, the low-stress silicon nitride of the first layers 20 has an internal stress in a range between 10 MPa and 500 MPa, or in a range between 10 MPa and 200 MPa, or in a range between 20 MPa and 100 MPa.

For example, a tensile stress above 20 MPa or above 10 MPa may be advantageous regarding the manufacturing of the membrane 12, while a stress below 500 MPa or 200 MPa or 100 MPa may be advantageous regarding the vibrational or acoustic properties.

In examples, the stochiometric portion of silicon in the low-stress silicon nitride exceeds a stochiometric portion of silicon in Si₃N₄. In other words, a portion of the silicon in the low-stress silicon nitride may be above 3/7.

For example, the portion of the silicon in the low-stress silicon nitride may be below 70%. In other words, in an example, the portion of the silicon in the low-stress silicon nitride is in a range between 3/7 and 7/10. In another example, the portion of the silicon in the low-stress silicon nitride is in a range between 45% and 60%.

A silicon ratio exceeding 3/7 provides for a low internal stress in the silicon nitride.

In examples, one or both of the two first layers 20 have a thickness in a range from 10 nm to 150 nm or in a range from 20 nm to 100 nm.

For example, the thickness relates to a dimension in a direction perpendicular to the plane, in which the first and second layers extend.

In examples, the two first layers have the same thickness. Thus, for example, the deflectable membrane may be structured symmetrical, what may be beneficial for the vibrational or acoustic properties.

In examples, the second layer 30 has a thickness in a range from 100 nm to 500 nm or in a range from 150 nm to 350 nm.

In other words, as described above with respect to FIG. 1, the MEMS transducer may comprise a stacked membrane consisting of poly-silicon and low-stress silicon nitride, which has low total stress due to highly doped poly-silicon and silicon-rich silicon nitride providing high acoustic compliance and higher robustness due to silicon nitride, e.g., compared to a membrane consisting of poly-silicon only.

FIG. 2 illustrates a further example of the MEMS transducer 10. All details described with respect to FIG. 1 may optionally be implemented in the MEMS transducer 10 of FIG. 2 individually or in any combination. According to the example of FIG. 2, the deflectable membrane comprises at least one corrugation (ring structure) 40.

For example, the corrugation 40 may further reduce the overall membrane stress thus improving acoustic compliance.

For example, the corrugation 40 of the deflectable membrane includes the two first layers 20 and the second layer 30. In other words, the two first layers 20 and the second layer 30 may be affected by the corrugation or may extend through the corrugation. Silicon nitride coverage on the corrugation may provide better robustness of the membrane 12.

For example, the corrugation 40 may extend along, e.g. in parallel to, the circumference of the deflectable membrane 12, e.g., as shown in FIG. 2 showing a cross-section.

In an example, the corrugation 40 has an extension, in a direction perpendicular to the deflectable membrane, e.g., in a direction perpendicular to the plane in which the deflectable membrane extends, in a range between 0.5 and 2 times a thickness of the deflectable membrane. In other words, the corrugation may extend out of a plane defined by a main surface region 14 of the membrane 12 by 0.5 and 2 times a thickness of the deflectable membrane.

In an example, the deflectable membrane 12 comprises a piezoelectric material.

The piezoelectric material may serve for providing an electrical signal which depends on a deflection of the deflectable membrane 12.

For example, the deflectable membrane may comprise a further layer comprising the piezoelectric material. For example, the further layer may be arranged adjacent to one of the two first layers 20 or between the two first layer 20 to be in contact to the doped silicon of the second layer 30. In examples, the further layer comprising the piezoelectric material does not necessarily extend over the entire membrane 12, but may be arranged within a region of the deflectable membrane.

In other words, the MEMS transducer 10 may be implemented as piezoelectric MEMS transducer. Alternatively, the MEMS transducer 10 may be implemented as capacitive MEMS transducer as will be described in the following.

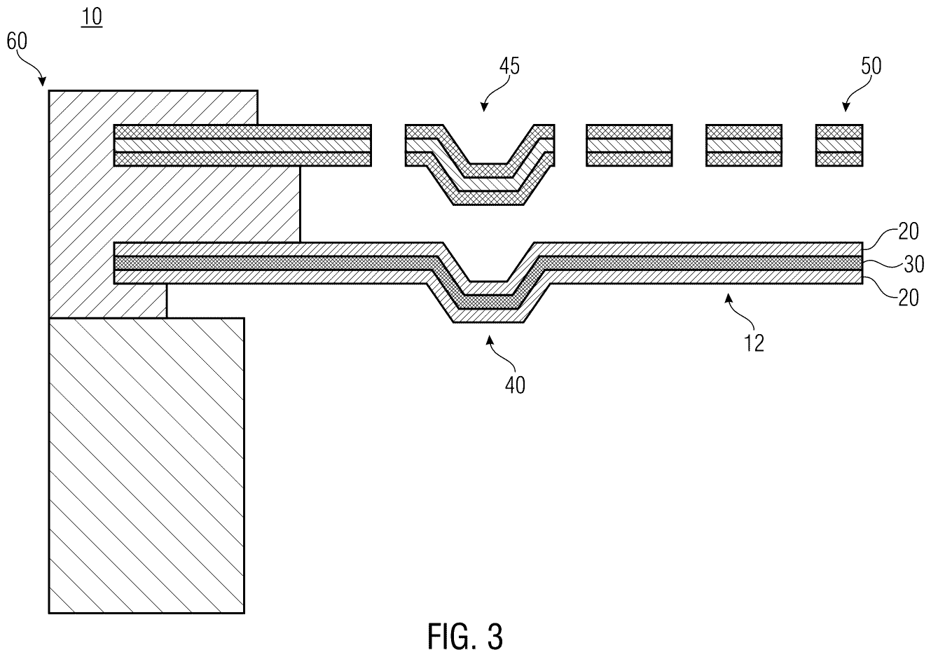

FIG. 3 illustrates a further example of the MEMS transducer 10. In this example, the MEMS transducer 10 further comprises a rigid electrode 50 arranged opposite to the deflectable membrane 12. The rigid electrode may also be referred to as backplate. The rigid electrode 50 may be insensitive to acoustic pressure, e.g., sound pressure. For example, the rigid electrode 50 may be a stiff membrane, e.g., a perforated stiff membrane. Note that FIG. 3 only illustrates a section of the MEMS transducer 10, namely the left section of a full view of the MEMS transducer 10 close to a left portion of the optional support structure 60.

The rigid electrode 50 may serve as reference for a capacitive measurement of a deflection of the deflectable membrane perpendicular to the plane in which the deflectable membrane extends. For example, the capacitive measurement may be performed between the rigid electrode 50 and the second layer 30, which may be conductive due to the doping of the silicon.

Accordingly, the rigid electrode 50 may be electrically conductive. For example, the rigid electrode may comprise an electrically conductive layer.

In other words, the MEMS transducer 10 may implement a capacitive transducer, e.g., a single back-plate transducer, e.g., a single back-plate sound transducer.

For example, the MEMS transducer 10 may be a MEMS microphone or a MEMS loudspeaker.

Although the rigid electrode is illustrated to have multiple layers in FIG. 3, the rigid electrode 50 may alternatively be implemented as one single homogeneous layer or as a multi-layered structure having two or more layers, e.g., three as shown in FIG. 3.

Note that FIG. 3 shows the rigid electrode 50 the combination of with the deflectable membrane 12, both structures being implemented with corrugations, as an example. However, the feature of the deflectable membrane 12 having a corrugation may be implemented independent from the feature of the MEMS transducer 10 comprising the rigid electrode 50. Thus, in a further example, the deflectable membrane 12 of the MEMS transducer 10 of FIG. 1 may comprise a corrugation, e.g., without being combined with a rigid electrode. In other words, although FIG. 3 shows the rigid electrode in combination with the deflectable membrane 12 having a corrugation, the implementation of a corrugation is independent of the MEMS transducer 10 having the rigid electrode. Other examples of the transducer of FIG. 3 may be implemented without corrugation.

In an example, the rigid electrode 50 has a corrugation 45, which may, for example, be positioned congruent to the corrugation 40 of the deflectable membrane. Such a structure may be easy to manufacture.

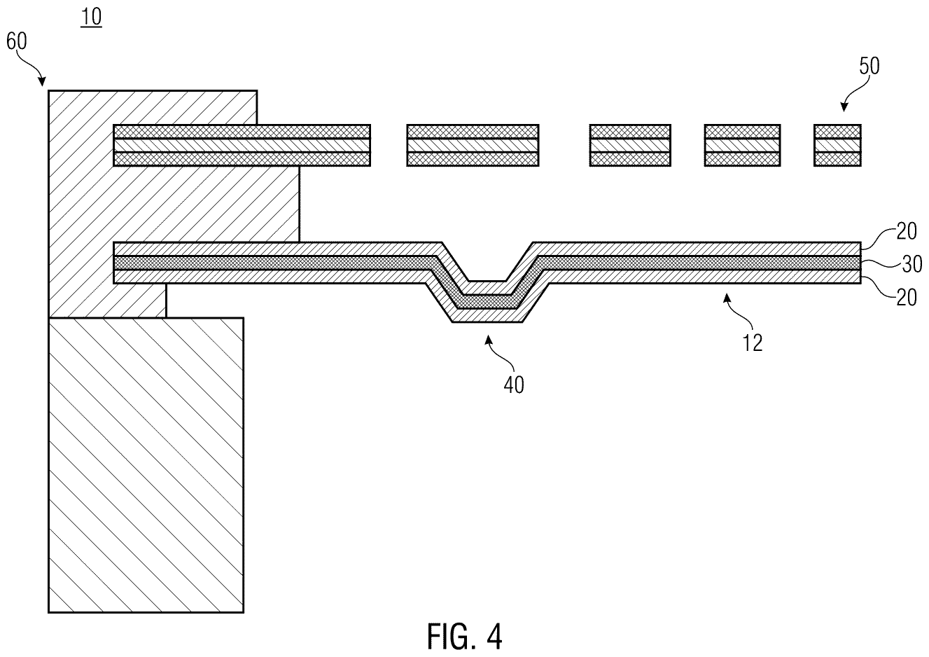

FIG. 4 illustrates a further example of the MEMS transducer 10, similar to the MEMS transducer 10 of FIG. 3, except that the rigid electrode 50 is implemented planar, or non-corrugated, e.g., without corrugation. Similar to FIG. 3, FIG. 4 only shows a section of the MEMS transducer 10, namely the left section of a full view of the MEMS transducer 10 close to a left portion of the optional support structure 60.

The combination of a corrugated membrane with a flat (planar, non-corrugated) backplate may improve the sensitivity and signal-to-noise ratio (SNR) of the device, as well as the robustness.

For example, a chemical mechanical polishing (CMP) process could be considered as an intermediate step to remove the corrugation in the rigid electrode to provide the rigid electrode to be planar.

FIG. 3 and FIG. 4 further show openings for pressure equalization in the rigid electrode 50, which may be implemented optionally.

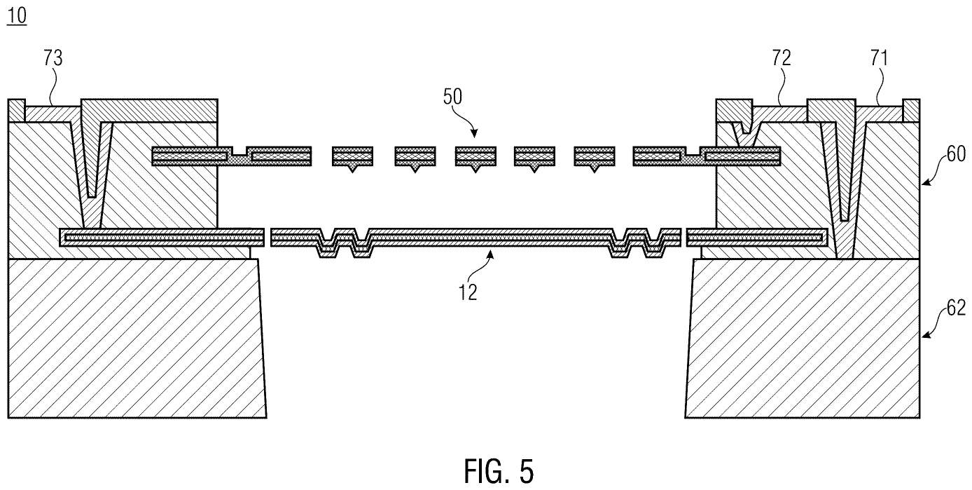

FIG. 5 illustrates another example of the MEMS transducer 10, which may be based on the MEMS transducer of FIG. 4. As shown in FIG. 5, the MEMS transducer 10, when implementing a capacitive transducer, may comprise a contacting structure 72 for electrically contacting the rigid electrode 50, and a further contacting structure 73 for electrically contacting the deflectable membrane 12, in particular, the second layer 30 of the deflectable membrane 12. The MEMS transducer may optionally further comprise a contacting structure 71 for electrically contacting a substrate 62, on which the supporting structure 60 may be arranged.

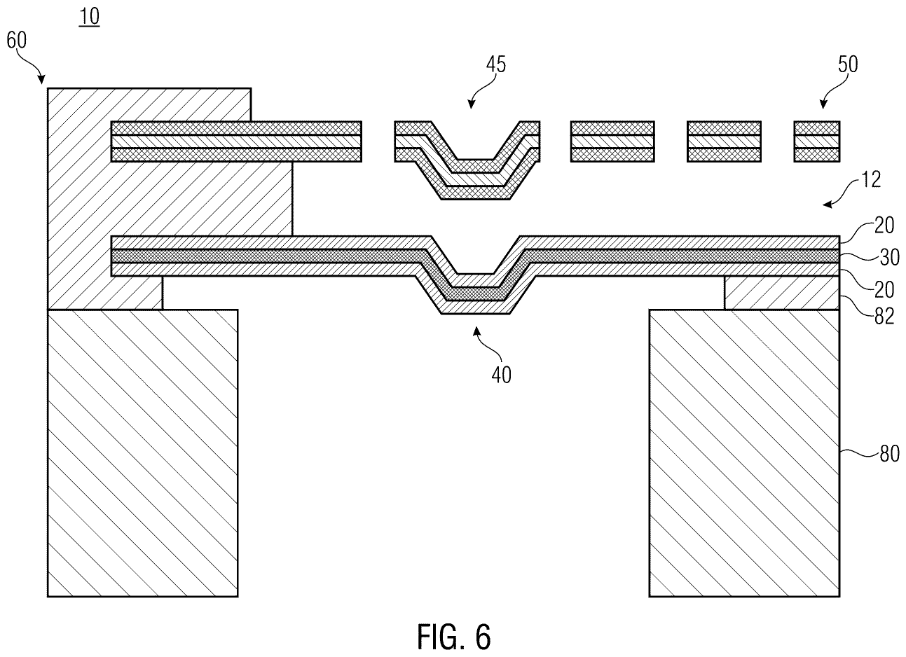

FIG. 6 illustrates a further example of the MEMS transducer 10, which may be similar, or correspond to, the MEMS transducer described with respect to FIG. 3, i.e., the MEMS transducer 10 of FIG. 6 may be a capacitive transducer. The MEMS transducer 10 of FIG. 6 further comprises a suspended mass 80 attached to the deflectable membrane 12, optionally by means of an attachment structure 82 as in FIG. 6. Similar to FIG. 3, FIG. 6 only shows a section of the MEMS transducer 10, namely the left section of a full view of the MEMS transducer 10 close to a left portion of the optional support structure 60.

The suspended mass 80 may serve as inertial mass. For example, the MEMS transducer 10 may implement an acceleration sensor or a vibration sensor.

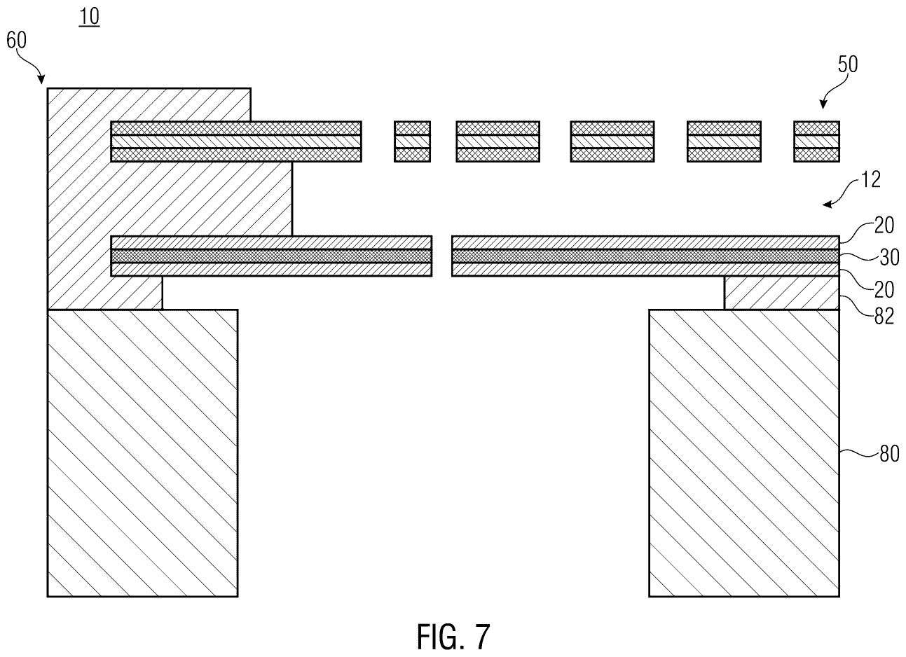

FIG. 7 illustrates another example of the MEMS transducer 10, which may be similar, or correspond to, the MEMS transducer 10 described with respect to FIG. 6, except that the deflectable membrane 12 and the rigid electrode 50 are implemented planar or non-corrugated, e.g., without corrugations. Similar to FIG. 3, FIG. 7 only shows a section of the MEMS transducer 10, namely the left section of a full view of the MEMS transducer 10 close to a left portion of the optional support structure 60.

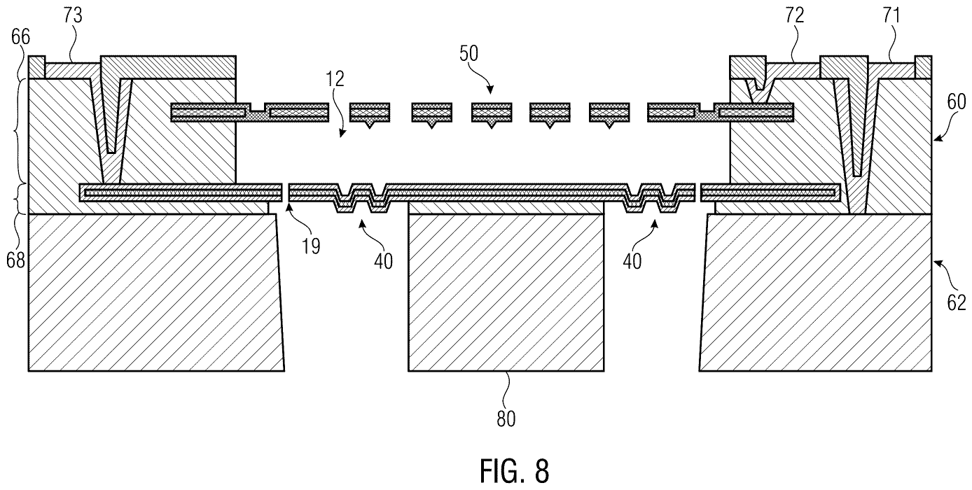

FIG. 8 illustrates another example of the MEMS transducer 10, which may correspond to the MEMS transducer 10 described with respect to FIG. 5, but additionally comprising the suspended mass 80 described with respect to FIG. 6 and FIG. 7.

As illustrated in FIG. 8 the deflectable membrane 12 may comprise vent holes 19 for pressure equalization. This feature is independent from the further details of FIG. 8 such as the suspended mass 80, the implementation as capacitive transducer and the corrugations 40.

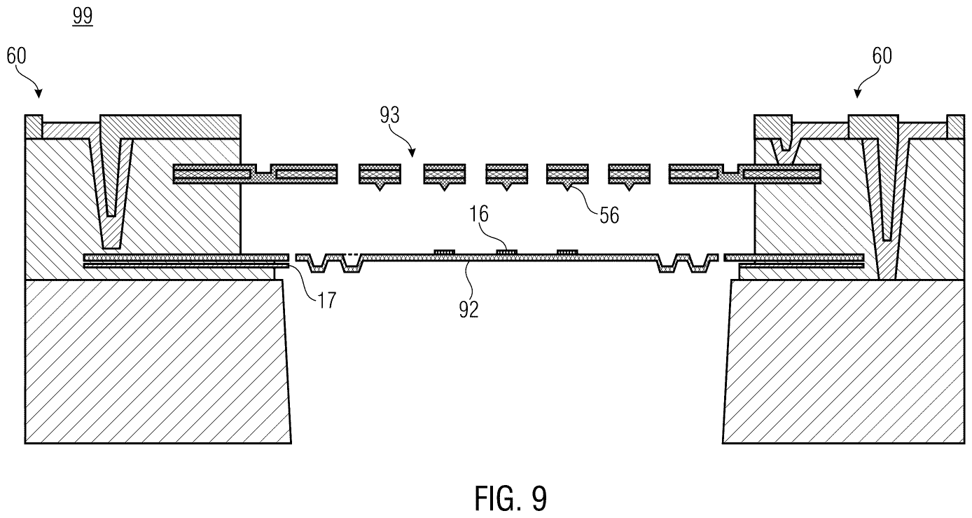

FIG. 9 illustrates a conventional single backplate MEMS transducer 99, which comprises landing pads 16 arranged on a deflectable membrane 92. The landing pads may serve to protect the membrane 92 from being damaged by spacers 56 arranged on the backplate 93, the spacers preventing the membrane 92 sticking to the backplate 93.

Due to the increased robustness of the deflectable membrane 12, arising from the usage of the first layers 20 comprising the low-stress nitride, examples of the present disclosure may be implemented without landing pads, thereby reducing the production cost.

Furthermore, conventional MEMS transducers may require tapers 17 on the suspension of the membrane 92 at the supporting structure 60. In contrast, examples of the present disclosure may be implemented with tapers at a suspension of the deflectable membrane 12 or without tapers, e.g., having a rigid suspension.

Furthermore, as shown in FIG. 9, but also in FIG. 5 and FIG. 8, a portion 68 of the supporting structure 60 arranged below the deflectable membrane may extend further to a center of the deflectable membrane (regarding a direction in the plane of the deflectable membrane) compared to a portion 66 of the supporting structure 60 arranged above the deflectable membrane, thereby increasing the robustness of the deflectable membrane. This excess may be referred to as full stack support, FSS. Due to the increased robustness of the deflectable membrane 12 according to the present disclosure, FSS may not be included, as illustrated in FIGS. 3, 4, 6, and 7.

Although FIG. 9 illustrates a MEMS transducer without suspended mass, the advantages of examples of the present disclosure explained with respect to FIG. 9 apply equivalently to MEMS transducers with suspended mass.

Although some aspects have been described as features in the context of an apparatus it is clear that such a description may also be regarded as a description of corresponding features of a method. Although some aspects have been described as features in the context of a method, it is clear that such a description may also be regarded as a description of corresponding features concerning the functionality of an apparatus.

In the foregoing description, it can be seen that various features are grouped together in examples for the purpose of streamlining the disclosure. This method of disclosure is not to be interpreted as reflecting an intention that the claimed examples require more features than are expressly recited in each claim. Rather, as the following claims reflect, subject matter may lie in less than all features of a single disclosed example. Thus, the following claims are hereby incorporated into the description, where each claim may stand on its own as a separate example. While each claim may stand on its own as a separate example, it is to be noted that, although a dependent claim may refer in the claims to a specific combination with one or more other claims, other examples may also include a combination of the dependent claim with the subject matter of each other dependent claim or a combination of each feature with other dependent or independent claims. Such combinations are proposed herein unless it is stated that a specific combination is not intended. Furthermore, it is intended to include also features of a claim to any other independent claim even if this claim is not directly made dependent to the independent claim.

The above-described examples are merely illustrative for the principles of the present disclosure. It is understood that modifications and variations of the arrangements and the details described herein will be apparent to others skilled in the art. It is the intent, therefore, to be limited only by the scope of the pending patent claims and not by the specific details presented by way of description and explanation of the examples herein.

What is claimed is:

1. A Micro-Electro-Mechanical-System (MEMS) transducer comprising:
two first layers each comprising low-stress silicon nitride; and
a second layer arranged between the two first layers, the second layer comprising doped silicon, the two first layers and the second layer being a deflectable membrane of the MEMS transducer.

2. The MEMS transducer according to claim 1, wherein the deflectable membrane comprises at least one corrugation.

3. The MEMS transducer according to claim 2, wherein the corrugation has an extension in a direction perpendicular to the deflectable membrane in a range between about 0.5 and about 2 times a thickness of the deflectable membrane.

4. The MEMS transducer according to claim 1, wherein the two first layers each consist of low-stress silicon nitride or the second layer consists of doped silicon.

5. The MEMS transducer according to claim 1, wherein the low-stress silicon nitride has an internal stress in a range between about 10 MPa and about 500 MPa.

6. The MEMS transducer according to claim 1, wherein a stochiometric portion of silicon in the low-stress silicon nitride exceeds a stochiometric portion of silicon in Si₃N₄.

7. The MEMS transducer according to claim 1, wherein at least one of the two first layers has a thickness in a range from about 10 nm to about 150 nm.

8. The MEMS transducer according to claim 1, wherein the two first layers have substantially the same thickness.

9. The MEMS transducer according to claim 1, wherein the second layer has a thickness in a range from about 100 nm to about 500 nm.

10. The MEMS transducer according to claim 1, wherein the second layer is arranged adjacent to each of the two first layers.

11. The MEMS transducer according to claim 1, wherein the deflectable membrane is substantially circular, and wherein a radius of the deflectable membrane is in a range between about 200 μm to about 750 μm.

12. The MEMS transducer according to claim 1, wherein a concentration of a dopant of the doped silicon is in a range between about 10¹⁹ cm⁻³ and about 10²¹ cm⁻³.

13. The MEMS transducer according to claim 1, further comprising:
a rigid electrode arranged opposite the deflectable membrane.

14. The MEMS transducer according to claim 13, wherein the rigid electrode is planar.

15. The MEMS transducer according to claim 13, wherein the rigid electrode is free of corrugations.

16. The MEMS transducer according to claim 1, wherein the deflectable membrane comprises a piezoelectric material.

17. The MEMS transducer according to claim 1, further comprising:
a suspended mass attached to the deflectable membrane.

18. The MEMS transducer according to claim 1, wherein the doped silicon is doped poly-silicon.

19. A Micro-Electro-Mechanical-System (MEMS) transducer comprising:
two first layers each consisting of low-stress silicon nitride; and
a second layer arranged between the two first layers, the second layer consisting of doped silicon, the two first layers and the second layer being a deflectable membrane of the MEMS transducer.

20. A Micro-Electro-Mechanical-System (MEMS) transducer comprising:
a deflectable membrane comprising two first layers and a second layer arranged therebetween, the two first layers each comprising low-stress silicon nitride and the second layer comprising doped silicon; and
a rigid electrode arranged opposite the deflectable membrane, the rigid electrode being planar and comprising an electrically conductive layer.
